(19) United States
(12) Patent Application Publication
(10) Pub. No.: US 2026/0123301 A1
(43) Pub. Date: Apr. 30, 2026

(54) WAFER STRUCTURE WITH A CONDUCTIVE COATING LAYER

(71) Applicant: TEXAS INSTRUMENTS INCORPORATED, DALLAS, TX (US)

(72) Inventors: ENIS TUNCER, DALLAS, TX (US); RONGWEI ZHANG, PLANO, TX (US)

(21) Appl. No.: 18/930,603

(22) Filed: Oct. 29, 2024

(51) Int. Cl. H01L 23/00; H01L 21/3205; H01L 23/29; H01L 23/31; H01L 25/065

(52) U.S. Cl. CPC H10P 14/412; H10W 74/147; H10W 74/47; H10W 90/00; H10W 72/07354; H10W 72/342; H10W 90/736

(57) ABSTRACT

A wafer structure comprises a semiconductor wafer having a first side opposite a second side in a longitudinal direction. The wafer structure also comprises active circuitry formed on the first side of the semiconductor wafer. The active circuitry demarcates a voltage boundary between a first voltage zone and a second voltage zone in the semiconductor wafer. The wafer structure further includes an insulation layer including an insulation coating and an insulation barrier. The insulation coating is formed on the second side of the semiconductor wafer and extends to an insulation surface in the longitudinal direction. The insulation barrier extends from the insulation surface to the first side of the semiconductor wafer at the voltage boundary. The wafer structure yet further includes a conductive coating layer formed proximate to the insulation surface of a conductive coating material.

### TECHNICAL FIELD

This description relates to a wafer structure with a conductive coating layer to reduce partial discharge.

### BACKGROUND

Greater packaging density of microelectronic devices is an ongoing goal of the computer industry. One method of increasing the density of microelectronic devices is to stack the individual microelectronic dice within these devices. One method of fabricating a stacked microelectronic device is to fabricate integrated circuitry on active surfaces of individual microelectronic wafers, stack them, then dice the stacked wafers into individual stacked microelectronic devices. However, high-voltage microelectronic devices are susceptible to voids forming in the wafer structure, which can lead to partial discharge and device failure.

### SUMMARY

A first example is related to a wafer structure to reduce partial discharge. The wafer structure comprises a semiconductor wafer having a first side opposite a second side in a longitudinal direction. The wafer structure also comprises active circuitry formed on the first side of the semiconductor wafer. The active circuitry demarcates a voltage boundary between a first voltage zone and a second voltage zone in the semiconductor wafer. The wafer structure further includes an insulation layer including an insulation coating and an insulation barrier. The insulation coating is formed on the second side of the semiconductor wafer and extends to an insulation surface in the longitudinal direction. The insulation barrier extends from the insulation surface to the first side of the semiconductor wafer at the voltage boundary. The wafer structure yet further includes a conductive coating layer formed proximate to the insulation surface of a conductive coating material.

A second example is related to an integrated circuit (IC) device including a wafer structure. The wafer structure comprises a semiconductor wafer having a first side opposite a second side in a longitudinal direction. The wafer structure also comprises active circuitry formed on the first side of the semiconductor wafer. The active circuitry demarcates a voltage boundary between a first voltage zone and a second voltage zone in the semiconductor wafer. The wafer structure further includes an insulation layer including an insulation coating and an insulation barrier. The insulation coating is formed on the second side of the semiconductor wafer and extends to an insulation surface in the longitudinal direction. The insulation barrier extends from the insulation surface to the first side of the semiconductor wafer at the voltage boundary. The wafer structure yet further includes a conductive coating layer of a conductive coating material forming a base surface of the wafer structure. The IC device also comprises a die attach layer affixed to the base surface of the wafer structure. The IC device further comprises a lead frame affixed to the conductive coating layer by the die attach layer.

A third example is related to a method for forming an integrated circuit (IC) device. The method comprises providing a semiconductor wafer having a first side opposite a second side in a longitudinal direction. The method also comprises forming active circuitry on the first side of the semiconductor wafer. The active circuitry demarcates a voltage boundary between a first voltage zone and a second voltage zone in the semiconductor wafer. The method further includes etching a first trench in the semiconductor wafer from the second side to the first side of the semiconductor wafer. The method yet further comprises depositing insulation material in the first trench and over the second side of the semiconductor wafer to form an insulation layer. The method comprises depositing a conductive coating material over the insulation layer to form a conductive coating layer of a wafer structure extending from a base surface of the conductive coating layer to the active circuitry.

### BRIEF DESCRIPTION OF THE DRAWINGS

FIG. 1 illustrates an example of a wafer structure having a conductive coating layer.

FIG. 2 illustrates an example of an integrated circuit (IC) device having a wafer structure with a conductive coating layer.

FIG. 3 illustrates an example of a first stage of a method for forming an IC device having a wafer structure with a conductive coating layer.

FIG. 4 illustrates an example of a second stage of the method for forming the IC device having the wafer structure and the conductive coating layer.

FIG. 5 illustrates an example of a third stage of the method for forming the IC device having the wafer structure with the conductive coating layer.

FIG. 6 illustrates an example of a fourth stage of the method for forming the IC device having the wafer structure with the conductive coating layer.

FIG. 7 illustrates an example of a fifth stage of the method for forming the IC device having the wafer structure with the conductive coating layer.

FIG. 8 illustrates an example of a sixth stage of the method for forming the IC device having the wafer structure with the conductive coating layer.

FIG. 9 illustrates an example of a seventh stage of the method for forming the IC device having the wafer structure with the conductive coating layer.

FIG. 10 illustrates an example of an eighth stage of the method for forming the IC device having the wafer structure with the conductive coating layer.

FIG. 11 illustrates an example of a ninth stage of the method for forming the IC device having the wafer structure with the conductive coating layer.

FIG. 12 illustrates an example of a tenth stage of the method for forming the IC device having the wafer structure with the conductive coating layer.

FIG. 13 illustrates a flowchart of an example method for forming the IC device having a wafer structure with a conductive coating layer.

### DETAILED DESCRIPTION

Partial discharge is a localized electrical discharge that occurs in a dielectric under high voltage stress. Designing and manufacturing of the electrical equipment is a complex process and air pockets left in the solid or liquid insulation contribute to the formation of partial discharges. These pockets of air or impurities have lower dielectric strength than the surrounding insulation, and thus, breakdown of the insulation occurs more easily. When electrical stress increases, a small discharge current starts to flow in these voids resulting in electric fields in the wafer structure. Progression of partial discharges over time leads to deterioration of the insulation and ultimately failure of the device.

In solid insulation of the wafer structure, partial discharges result in the formation of sparking channels that branch out. Here, metallization of the wafer structure after deposition of the insulation dampens the current flow and corresponding electric fields. The metallization can be formed as a conductive coating layer of conductive coating material over the insulation. Additionally, while high-voltage applications typically use non-conducting die attach materials, the conductive coating layer allows a conductive die attach material to be used with the wafer structure. The conductive die attach material further reduces the current and electric fields, thereby mitigating the partial discharge and improving the longevity of high-voltage devices.

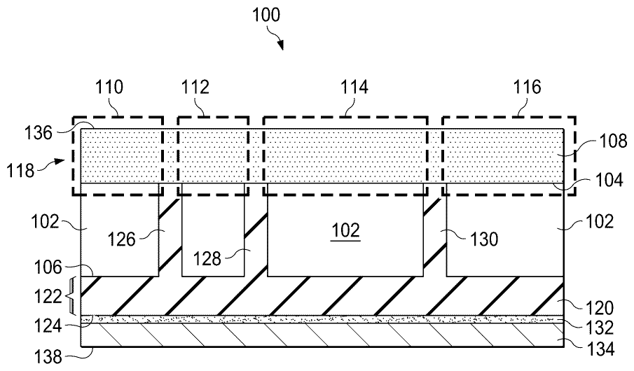

FIG. 1 illustrates an example of a wafer structure having a conductive coating layer. The wafer structure 100 includes a wafer 102 having a first side 104 opposite a second side 106. The wafer 102 is a substrate, such as silicon, silicon carbide, or other suitable material, either in substantially pure form or in combination with additional materials. As another example, the wafer 102 is a single crystal material, such as a single crystal silicon substrate. As yet another example, the wafer 102 is a complementary metal-oxide semiconductor (CMOS) substrate. The formation of the wafer 102 is dependent on the application of the resulting IC device.

Active circuitry 108 is formed on the first side 104 of the wafer 102. The active circuitry 108 includes components such as one or more passive elements (e.g., resistors, capacitors, transistors, inductors, etc.) and/or one or more sources (e.g., voltage and/or current sources, etc.). In some examples, the active circuitry 108 includes high voltage devices such as a high voltage electrostatic discharge (ESD) device with a high voltage field MOSFET, etc.

The different high voltage components of the active circuitry 108 result in different voltage zones including a first voltage zone 110, a second voltage zone 112, a third voltage zone 114, and a fourth voltage zone 116. The first voltage zone 110 corresponds to the active circuitry 108 generating a first voltage and the second voltage zone 112 corresponds to the active circuitry 108 generating a second voltage higher than the first voltage. The third voltage zone 114 corresponds to the active circuitry 108 generating a third voltage. In some examples, the third voltage is greater than the second voltage. In other examples, the fourth voltage zone 116 corresponds to the active circuitry 108 generating a fourth voltage higher than the third voltage. The voltage zones 110-116 are separated by voltage boundaries. For example, a voltage boundary 118 is positioned between a first voltage zone 110 and a second voltage zone 112 in the wafer 102.

An insulation layer 120 is deposited on and through a second side 106 of the wafer 102. The insulation layer 120 is formed of an insulation material is nonconductive, and is, for example, parylene, polybenzoxazole (PBO), SU-8, Ajinomoto Build-up Film (ABF), spin-on-glass (SOG), polyimide (PI), polyphenylene ether (PPE), polyphenylene oxide (PPO), Bismaleimide (BMI), Benzocyclobutene (BCB) or other suitable material with similar properties. The insulation layer 120 includes an insulation coating 122 formed on the second side 106 of the wafer 102 and extends to an insulation surface 124 in the longitudinal direction. The insulation layer 120 also includes one or more insulation barriers, such as a first insulation barrier 126, a second insulation barrier 128, and a third insulation barrier 130. The insulation barriers 126-130 extends from the second side 106 to the first side 104 of the wafer 102. The insulation barriers have a trench width of approximately 10 microns extending in a lateral direction approximately orthogonal to the longitudinal direction. The insulation barriers 126-130 extend from the second side 106 of the wafer 102 to the first side 104 of the wafer 102 in the longitudinal direction at a voltage boundary, such as the voltage boundary 118. For example, the voltage boundary 118 extends from the second side 106 to the first side 104 between the first voltage zone 110 and the second voltage zone 112. The first insulation barrier 126 electrically isolates the first voltage zone 110 and the second voltage zone 112 and mitigates metal migration due to the voltage differential between the first voltage zone 110 and the second voltage zone 112.

An adhesive layer 132 is formed on the insulation surface 124 of the insulation layer 120. The adhesive layer 132 can be one of the passivation materials employed in back-end-of-line, silicon oxide, silicon nitride, spin-on-glass, etc. In other examples, the adhesive layer 132 could be chromium, titanium, titanium-tungsten alloy, titanium nitride, tantalum or tantalum nitride. The adhesive layer 132 can be formed by sputtering. In some examples, the adhesive layer 132 has a thickness in the longitudinal direction of approximately 10 nanometers to 10 microns, for example, one micron. The adhesive layer 132 being less than 10 nanometers may reduce coverage of the adhesive layer 132 thereby reducing adhesion. The adhesive layer 132 being greater than 10 microns increases cost.

A conductive coating layer 134 is applied to the adhesive layer 132. The adhesive layer 132 bonds the conductive coating layer 134 to the insulation layer 120. The conductive coating layer 134 can be formed of a backside metallization material such as aluminum, titanium, silver, gold, nickel-vanadium, and combinations thereof. The adhesive layer 132 is deposited using a sputtering technique. The conductive coating layer 134 has a thickness in the longitudinal direction of approximately 1 nanometer to 10 microns. If the thickness of the conductive coating layer 134 is less than 1 nanometer, then the resistance suffers. The thickness of the conductive coating layer 134 being greater than 10 microns increases cost. The conductive coating layer 134 reduces current flow between the voltage zones 110-116 of the active circuitry 108 through the wafer 102. The wafer structure 100 extends from the upper surface 136 of the active circuitry 108 to a base surface 138 of the conductive coating layer 134. In some examples, the wafer structure 100 is a silicon on insulator (SOI) structure for a high voltage semiconductor device.

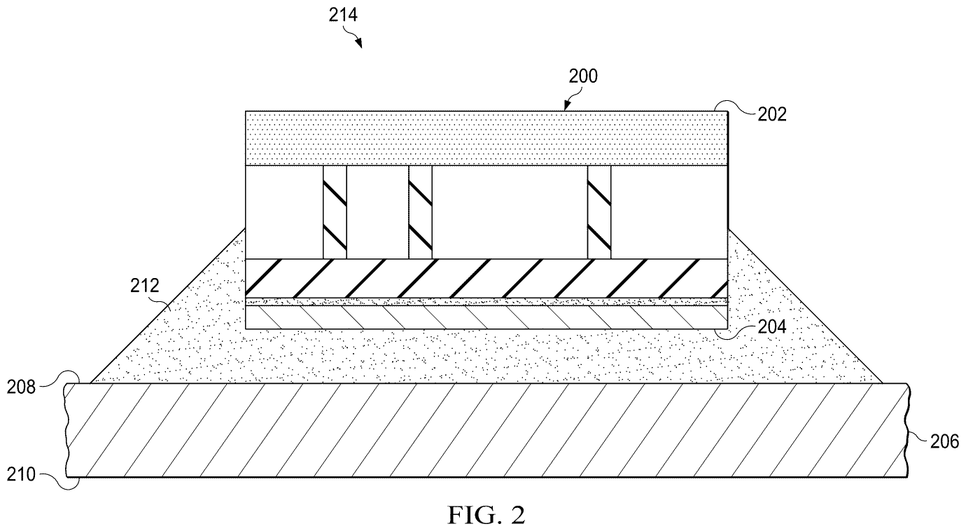

FIG. 2 illustrates an example of an integrated circuit (IC) device having a wafer structure 200 (e.g., the wafer structure 100 of FIG. 1). The wafer structure 200 extends from an upper surface 202 (e.g., the upper surface 136 of FIG. 1) of the active circuitry to a base surface 204 (e.g., the base surface 138 of FIG. 1) of a conductive coating layer of the wafer structure 200.

A lead frame 206 is formed of an electrically conductive coating material, such as copper, palladium, gold, silver, or other appropriate conductive metal or metal alloy with similar properties. For example, the lead frame 206 is formed of a copper sheet. In one example, the lead frame 206 is a routable lead frame. The lead frame 206 extends from a first side 208 to a second side 210. The wafer structure 200 is affixed to the lead frame 206 with a die attach layer 212 affixed to the base surface 204 of the wafer structure 200.

The material of the die attach layer is based on the application of the wafer structure 200. In some examples, the die attach layer 212 is a nonconductive die attach layer formed of a nonconductive coating material, such as a polyimide material, such as epoxy resin, polybenzoxazole, polyimide, benzocyclobutene, and combinations thereof. In other examples, the die attach layer 212 is a conductive die attach layer formed of a conductive coating material. The conductive die attach layer may be a thin metal layer and/or a metal filled polymer (e.g., silver-filled epoxies). The die attach layer 212 has a die attach layer thickness of approximately 1-100 microns. The die attach layer being less than 1 micron may subject the die attach layer 212 to stress and degrade delamination performance. The die attach layer 212 being greater than 100 microns increases cost.

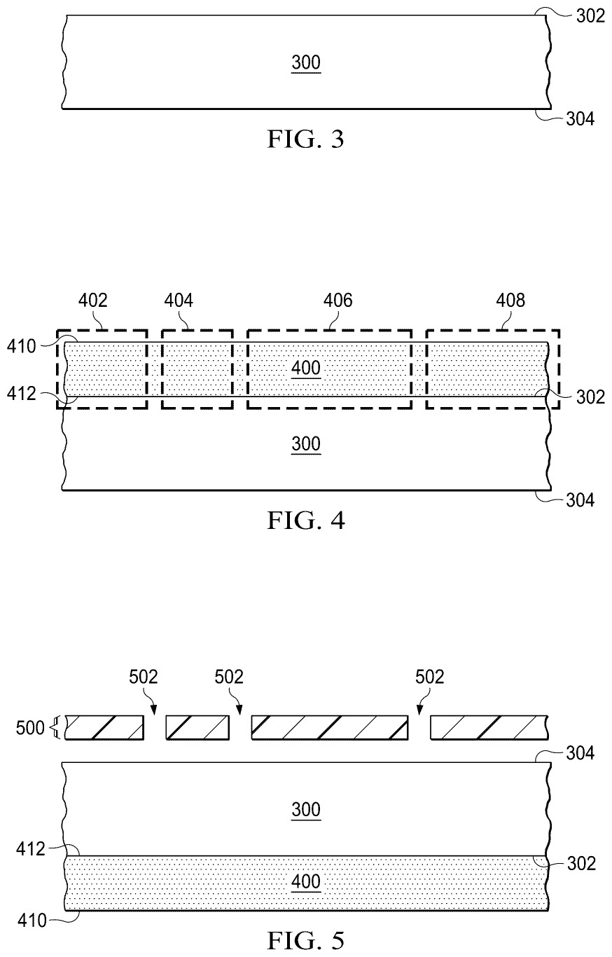

The wafer structure 200, the lead frame 206, and the die attach layer 212 form an IC device 214. FIGS. 3-9 illustrate stages of a method for fabricating an IC device, such as the IC device 214 of FIG. 2. For purposes of simplification, FIGS. 3-9 employ the same reference numbers to denote the same structure.

FIG. 3 illustrates an example of a first stage of a method for forming an IC device. In the first stage, a wafer 300 (e.g., the wafer 102 of FIG. 1) is provided. The wafer 300 has a first side 302 opposite a second side 304. The wafer 300 is formed of a substrate material, such as silicon, germanium, gallium arsenide, indium phosphide, silicon carbide, or other material suitable for structural support.

FIG. 4 illustrates an example of a second stage of the method for forming the IC device. Active circuitry 400 (e.g., the active circuitry 108 of FIG. 1) is formed on the first side 302 of the wafer 300. The active circuitry 400 includes one or more high voltage devices. As one example, the high voltage devices include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, etc. The active circuitry 400 may also include passive circuit elements, such as capacitors, inductors, fuses, resistors, and interconnects. In some examples, the active circuitry 400 is formed of a printed circuit board (PCB). The different devices, whether the devices are high voltage devices, passive devices, etc., have different voltages causing voltage differentials to exist on the active circuitry 400.

Voltage zones are formed in active circuitry 400 due to the different devices of the active circuitry 400. For example, a first voltage zone 402, a second voltage zone 404, a third voltage zone 406, and a fourth voltage zone 408 are formed based on different voltages generated by different components of the active circuitry 400. The active circuitry 400 extends from a first surface 410 to a second surface 412. In some examples, the voltage zones 402-408 are bounded by the first surface 410 to the second surface 412. In other examples, the voltage zones 402-408 extend beyond the second surface 412 into the wafer 300. As one example, the distance the voltage zones 402-408 extend into the wafer 300 through the first side 302 is proportional to the value of the voltage in the voltage zone.

FIG. 5 illustrates an example of a third stage of the method for forming the IC device. In the third stage, a photomask 500 is applied to the second side 304 of the wafer 300. In one example, the photomask 500 is opaque, blocking a portion of the second side 304 from irradiation used for patterning. The photomask 500 includes openings 502 that allow irradiation to impact the second side 304.

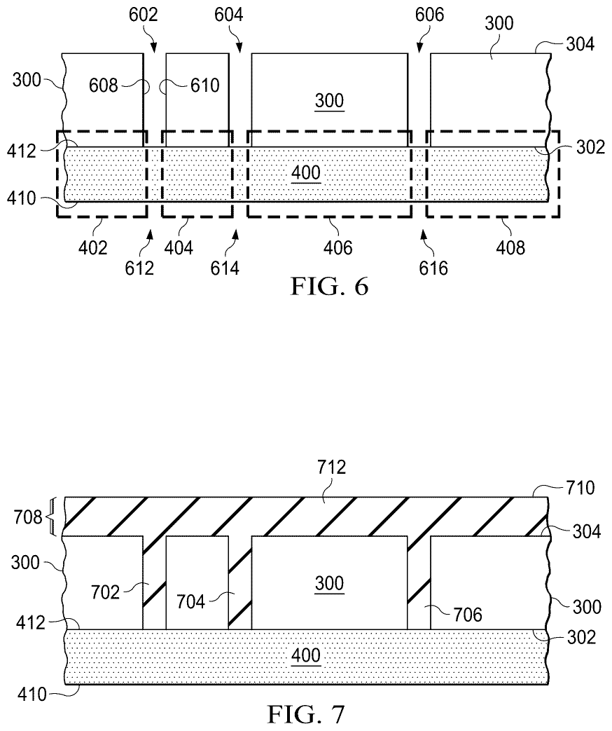

FIG. 6 illustrates an example of a fourth stage of the method for forming the IC device having the wafer structure with the conductive coating layer. The irradiated portions of the second side 304 are removed by applying a developer material. For example, a dry plasma etch is performed to remove the irradiated portions from the second side 304. The substrate material of the wafer 300 is etched from the second side 304 to the first side 302 of the wafer 300 and the photomask 500 is removed. The etched substrate material forms a first trench 602, a second trench 604, and a third trench 606. The first trench 602 has a first sidewall 608 opposite a second sidewall 610 in the horizontal direction. In some examples, first sidewall 608 opposite a second sidewall 610 are patterned with light or ablation laser such that the first sidewall 608 and the second sidewall 610 have a regular even surface.

The trenches 602, 604, including sidewalls 608, 610 are formed over voltage boundaries between voltage zones. For example, the first trench 602 is formed over a first voltage boundary 612 (e.g., the voltage boundary 118 of FIG. 1) between the first voltage zone 402 and the second voltage zone 404. As one example the first sidewall 608 of the first trench 602 is positioned over the first voltage zone 402 and the second sidewall 610 is positioned over the second voltage zone 404. The second trench 604 is formed over a second voltage boundary 614 between the second voltage zone 404 and the third voltage zone 406. The third trench 606 is formed over a third voltage boundary 616 between the third voltage zone 406 and the fourth voltage zone 408.

FIG. 7 illustrates an example of a fifth stage of the method for forming the IC device. In the fifth stage, a first trench 602, a second trench 604, and a third trench 606 are filled with the insulation material to form a first insulation barrier 702 (e.g., the first insulation barrier 126 of FIG. 1), a second insulation barrier 704 (e.g., the second insulation barrier 128 of FIG. 1), and a third insulation barrier 706 (e.g., the third insulation barrier 130 of FIG. 1), respectively. The insulation material is also applied to the second side 304 of the wafer 300 to form an insulation coating 708 (e.g. the insulation coating 122 of FIG. 1). The insulation coating 708 has a planar surface 710.

The combination of the insulation barriers 702-706 and the insulation coating 708 form an insulation layer 712 (e.g., the insulation layer 120 of FIG. 1). The insulation barriers 702-706 have sidewalls corresponding to the first sidewall 608 and the second sidewall 610 in the horizontal direction. Because the first sidewall 608 and the second sidewall 610 have a regular even surface, the sidewalls of the insulation barriers 702-706, have a smooth surface extending through the wafer 300 approximately orthogonal to the first side 302 of the wafer. The insulation barriers 702-706 extend in the horizontal direction corresponding to the trench width.

Deposition techniques are used to form the approximately planar surface 710 of the insulation material. In some examples, the deposition techniques include a spin coating operation, a splay coating operation, or a lamination operation to achieve the planar surface 710 of the insulation material. In another example, the insulation material is deposited by submerging the structure shown in FIG. 6 in the insulation material or solution thereof as a pre-dipping operation. The pre-dipping operation allows the insulation material or solution thereof to fill the trenches 702-706. The pre-dipping operation is followed by a spin coating operation to remove excess insulation material from the insulation material or the solution thereof. The insulation material of the insulation layer 712 is a non-conductive material, such as parylene, polyimide (PI), polybenzoxazole (PBO), SU-8, Ajinomoto Build-up Film (ABF) or other suitable material with similar properties.

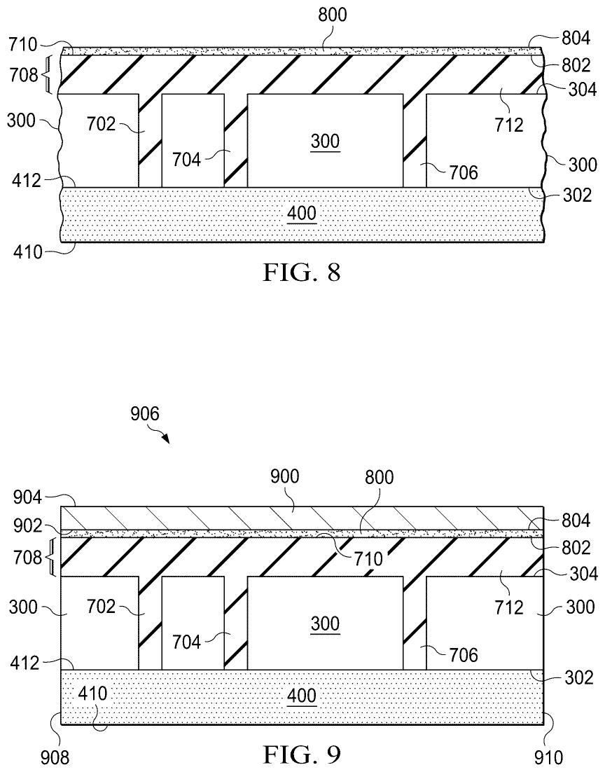

FIG. 8 illustrates an example of a sixth stage of the method for forming the IC device. In the sixth stage, an adhesive layer 800 is deposited on the planar surface 710 of the insulation layer 712. The adhesive layer 800 has a first surface 802 opposite a second surface 804 in the longitudinal direction. As one example, the adhesive layer 800 is formed of a passivation material, for example, silicon dioxide. The adhesive layer has a thickness defined between the first surface 802 and the second surface 804. The adhesive layer 800 has a thickness in the longitudinal direction of approximately 10 nanometers to 10 microns, for example, one micron. The adhesive layer 800 being less than 10 nanometers may reduce coverage of the adhesive layer 800 thereby reducing adhesion. The adhesive layer 800 being greater than 10 microns increases cost. In some examples, the adhesive layer 800 is polished (e.g., by chemical-mechanical polishing) and prepared for direct bonding.

FIG. 9 illustrates an example of a seventh stage of the method for forming the IC device. A conductive coating layer is 900 deposited over the insulation layer 712. The conductive coating layer 900 has a first surface 902 opposite a base surface 904 in the longitudinal direction with a thickness defined between the first surface 902 and the base surface 904 of approximately 1 nanometer to 10 microns. If the thickness of the conductive coating layer 900 is less than 1 nanometer, then the resistance suffers. The thickness of the conductive coating layer 900 being greater than 10 microns increases cost. The first surface 902 is deposited on the second surface 804 of the adhesive layer 800. The adhesive layer 800 provides adhesion of the conductive coating layer 900 to the planar surface 710 of the insulation coating 708. In some examples, a plasma process is performed to increase the adhesion between the insulation layer 712 and the conductive coating layer 900.

The conductive coating layer 900 is formed conductive coating material such as a backside metallization material, for example, one or more of aluminum, titanium, silver, gold, nickel-vanadium, and combinations thereof. In some examples, the conductive coating material is deposited using a sputtering technique. In some examples, a seed layer is formed between the adhesive layer 800 and the conductive coating layer 900. The seed layer may be formed by a sputtering process or by a chemical vapor deposition (CVD) process to apply the conductive coating layer 900 to the second surface 804 of the adhesive layer 800.

The wafer 300, the active circuitry 400, the insulation barrier 702-706, the insulation coating 708, the adhesive layer 800, and the conductive coating layer 900 form a wafer structure 906. For example, the wafer structure 906 extends from the first surface 410 of the active circuitry 400 to the base surface 904 of the conductive coating layer 900. In some examples, the wafer structure 906 extends from a first wafer sidewall 908 to a second wafer sidewall 910. For example, the wafer 300, the active circuitry 400, the insulation barrier 702-706, the insulation coating 708, the adhesive layer 800, and the conductive coating layer 900 have edges that are approximately collinear forming the first wafer sidewall 908. Similarly, the wafer 300, the active circuitry 400, the insulation barrier 702-706, the insulation coating 708, the adhesive layer 800, and the conductive coating layer 900 have edges that are approximately collinear forming the second wafer sidewall 910 opposite the first wafer sidewall 908 in the lateral direction.

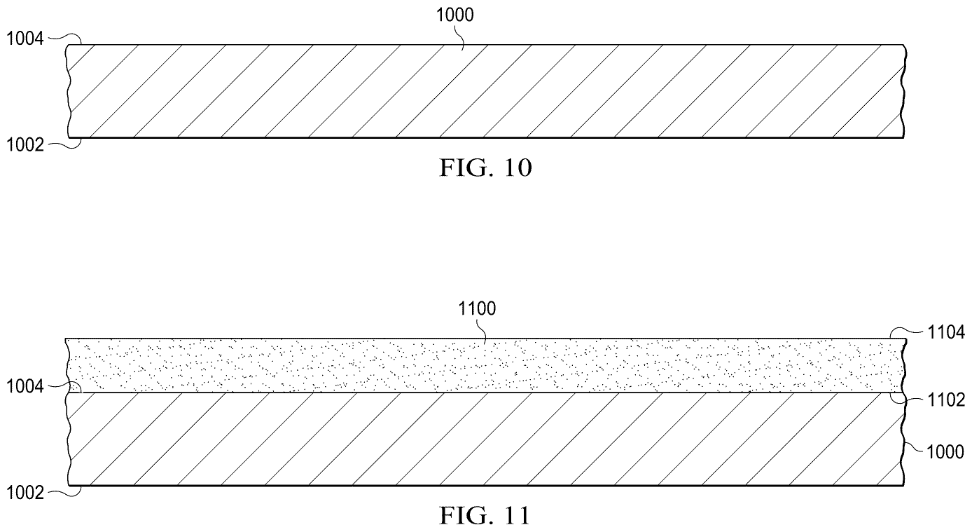

FIG. 10 illustrates an example of an eighth stage of the method for forming the IC device. The eighth stage includes providing a lead frame 1000 (e.g., the lead frame 206 of FIG. 2). The lead frame 1000 may be formed from a conductive sheet. For example, the lead frame 1000 may be formed of copper. The lead frame 1000 includes a first surface 1002 (e.g., the first side 208 of FIG. 2) and a second surface 1004 (e.g., the second surface 1004 of FIG. 2) opposite the first surface 1002.

FIG. 11 illustrates an example of a ninth stage of the method for forming the IC device having the wafer structure with a conductive adhesive layer. A die attach layer 1100, extending from a first surface 1102 to a second surface 1104, is applied to the lead frame 1000. The first surface 1102 of the die attach layer is applied to the second surface 1004 of the lead frame 1000. The die attach layer 1100 is formed of a die attach material. The die attach material may be in any suitable form such as a paste, a film, or a preform.

The die attach layer 1100 may be a conductive die attach layer, formed of a conductive material, or a non-conductive die attach layer, formed of a non-conductive material. For example, a conductive die attach layer is formed of a conductive die attach material that includes particles of one or more metallic materials that are capable of assuming a conductive structure when exposed to conditions suitable for sintering, such as elevated temperatures. For example, the conductive die attach material may include particles of silver, gold, copper, nickel, palladium, and/or other sinterable materials configured to produce a sintered metal when exposed to a temperature sufficient for sintering to occur. As another example, the die attach layer 1100 may be a non-conductive die attach layer that includes organic, epoxy, or polymer material, such as a resin. The die attach layer 1100 may be applied using deposition techniques include a spin coating operation, a splay coating operation, etc. The die attach layer 1100 has a die attach layer thickness of approximately 1-100 microns. The die attach layer being less than 1 micron may subject the die attach layer 1100 to stress and degrade delamination performance. The die attach layer 1100 being greater than 100 microns increases cost.

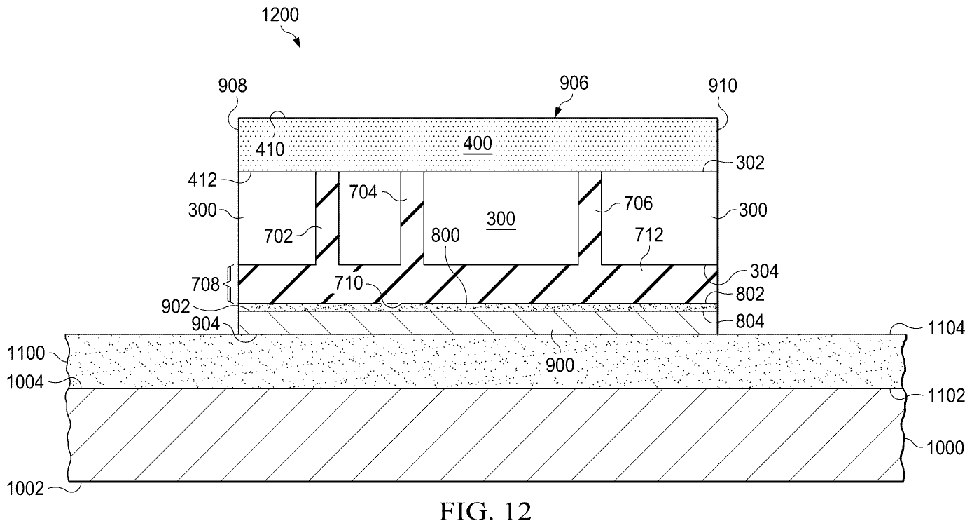

FIG. 12 illustrates an example of a tenth stage of the method for forming an IC device 1200 (e.g., the IC device 214 of FIG. 2) having the wafer structure 906 with a conductive coating layer 900. The wafer structure 906 is applied the lead frame 1000 by the die attach layer 1100. The conductive coating layer 900 provides a metallization of the wafer structure 906 that dampens the current flow and resulting electric fields. While high-voltage applications that use the active circuitry 400 typically use non-conducting die attach materials for the die attach layer 1100, the conductive coating layer 900 allows a conductive die attach material to be used with the wafer structure 906 to reduce the current and electric fields thereby mitigating the partial discharge. Additionally, non-conducting die attach materials for the die attach layer 1100 may be used and the conductive coating layer will still reduce the current and electric fields to mitigate the partial discharge.

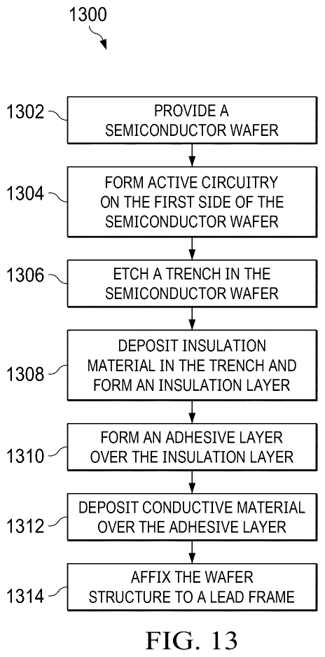

FIG. 13 illustrates an example method 1300 for forming an IC device, such as the IC device of FIG. 2. At block 1302, the method 1300 includes providing a semiconductor wafer (e.g., wafer 102 of FIG. 1, the wafer 300 of FIG. 3) is provided. The wafer having a first side (e.g., the first side 104 of FIG. 1, the first side 302 of FIG. 3) opposite a second side (e.g., the second side 106 of FIG. 1, the second side 304 of FIG. 3). In some examples, wafer is a silicon substrate.

At block 1304, the method 1300 includes forming active circuitry (e.g., the active circuitry 108 of FIG. 1, the active circuitry 400 of FIG. 4) on the first side of the semiconductor wafer. The active circuitry demarcates a voltage boundary (e.g., a voltage boundary 118 of FIG. 1, a first voltage boundary 612, a second voltage boundary 614, a third voltage boundary 616 of FIG. 6) between a first voltage zone (e.g., a first voltage zone 110 of FIG. 1, a first voltage zone 402 of FIG. 4) and a second voltage zone (e.g., a second voltage zone 112 of FIG. 1, a second voltage zone 404 of FIG. 4) in the semiconductor wafer.

At block 1306, the method 1300 includes etching a first trench (e.g., a first trench 602 of FIG. 6) in the semiconductor wafer from the second side of the semiconductor wafer to the first side of the semiconductor wafer.

At block 1308, the method 1300 includes depositing insulation material in the first trench and over the second side of the semiconductor wafer to form an insulation layer (e.g., the insulation layer 120 of FIG. 1, the insulation layer 712 of FIG. 7).

At block 1310, the method 1300 includes depositing an adhesive layer (e.g., the adhesive layer 132 of FIG. 1, the adhesive layer 800 of FIG. 8) on a planar surface (e.g., the planar surface 710 of FIG. 7) of the insulation layer.

At block 1312, the method 1300 includes depositing a conductive coating material over the insulation layer to form a conductive coating layer (e.g., the conductive coating layer 134 of FIG. 1, the conductive coating layer 900 of FIG. 9) of a wafer structure (e.g., the wafer structure 100 of FIG. 1, the wafer structure 200 of FIG. 1, the wafer structure 906 of FIG. 9) extending from a base surface (e.g., the base surface 138 of FIG. 1, the base surface 204 of FIG. 2, the base surface 904 of FIG. 9) of the conductive coating layer to the active circuitry. As one example, the wafer structure is a silicon on insulator (SOI) structure.

At block 1314, the method 1300 includes affixing the wafer structure to a lead frame (e.g., the lead frame 206 of FIG. 2, the lead frame 1000 of FIG. 10) using a die attach layer (e.g., the die attach layer 212 of FIG. 2, the die attach layer 1100 of FIG. 11). The die attach layer may be formed of a conductive coating material or non-conductive coating material. The wafer structure, the die attach layer, and the lead frame form an IC device (e.g., the IC device 214 of FIG. 2, the IC device 1200 of FIG. 12). The IC device may be is a high voltage semiconductor device.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A wafer structure to reduce partial discharge, the wafer structure comprising:
a semiconductor wafer having a first side opposite a second side in a longitudinal direction;
active circuitry formed on the first side of the semiconductor wafer, wherein a voltage boundary is positioned between a first voltage zone and a second voltage zone in the semiconductor wafer;
an insulation layer including an insulation coating and an insulation barrier, wherein the insulation coating formed on the second side of the semiconductor wafer and extends to an insulation surface in the longitudinal direction, and wherein the insulation barrier extends from the second side to the first side of the semiconductor wafer at the voltage boundary; and
a conductive coating layer formed proximate to the insulation surface of a conductive coating material.

2. The wafer structure of claim 1, wherein the conductive coating material is a backside metallization material.

3. The wafer structure of claim 1, wherein the conductive coating layer has a thickness in the longitudinal direction of approximately 1 nanometer to 10 microns.

4. The wafer structure of claim 1, further comprising:
an adhesive layer that separates the insulation layer and the conductive coating layer in the longitudinal direction, wherein the adhesive layer provides adhesion of the conductive coating layer to the insulation layer.

5. The wafer structure of claim 4, wherein the adhesive layer is formed of a passivation material and has a thickness in the longitudinal direction of approximately one micron.

6. The wafer structure of claim 1, wherein the first voltage zone corresponds to the active circuitry generating a first voltage and the second voltage zone corresponds to the active circuitry generating a second voltage higher than the first voltage, and wherein the insulation barrier electrically isolates the first voltage zone and the second voltage zone.

7. The wafer structure of claim 6, wherein the insulation layer is formed of parylene, spin-on-glass (SOG), polyimide (PI), polyphenylene ether (PPE), polyphenylene oxide (PPO), Bismaleimide (BMI), or Benzocyclobutene (BCB).

8. The wafer structure of claim 6, wherein the insulation barrier has a trench width of approximately 5 to 100 microns extending in a lateral direction approximately orthogonal to the longitudinal direction.

9. The wafer structure of claim 1, wherein the wafer structure is a silicon on insulator (SOI) structure for a high voltage semiconductor device.

10. An integrated circuit (IC) device comprising:
a wafer structure comprising:
a semiconductor wafer having a first side opposite a second side in a longitudinal direction;
active circuitry formed on the first side of the semiconductor wafer, wherein the active circuitry demarcates a voltage boundary between a first voltage zone and a second voltage zone in the semiconductor wafer;
an insulation layer including an insulation coating and an insulation barrier, wherein the insulation coating formed on the second side of the semiconductor wafer and extends to an insulation surface in the longitudinal direction, and wherein the insulation barrier extends from the insulation surface to the first side of the semiconductor wafer at the voltage boundary; and
a conductive coating layer of a conductive coating material forming a base surface of the wafer structure;
a die attach layer affixed to the base surface of the wafer structure; and
a lead frame affixed to the conductive coating layer by the die attach layer.

11. The IC device of claim 10, wherein the die attach layer is a conductive die attach layer.

12. The IC device of claim 10, wherein the die attach layer is a nonconductive die attach layer.

13. The IC device of claim 10, further comprising:
an adhesive layer that separates the insulation layer and the conductive coating layer in the longitudinal direction, wherein the adhesive layer provides adhesion of the conductive coating layer to the insulation layer.

14. The IC device of claim 10, wherein the wafer structure is a silicon on insulator (SOI) structure and the IC device is a high voltage semiconductor device.

15. A method for forming an integrated circuit (IC) device, the method comprising:
providing a semiconductor wafer having a first side opposite a second side in a longitudinal direction;
forming active circuitry on the first side of the semiconductor wafer, wherein the active circuitry demarcates a voltage boundary between a first voltage zone and a second voltage zone in the semiconductor wafer;
etching a first trench in the semiconductor wafer from the second side to the first side of the semiconductor wafer;
depositing insulation material in the first trench and over the second side of the semiconductor wafer to form an insulation layer; and
depositing a conductive coating material over the insulation layer to form a conductive coating layer of a wafer structure extending from a base surface of the conductive coating layer to the active circuitry.

16. The method of claim 15, wherein the conductive coating material includes one or more of aluminum, titanium, silver, gold, nickel-vanadium, and combinations thereof deposited using a sputtering technique.

17. The method of claim 15, wherein the conductive coating material is deposited in a metal sputtering technique to form a conductive coating layer having a thickness in the longitudinal direction of approximately 1 nanometer to 10 microns.

18. The method of claim 15, further comprising:
affixing the wafer structure to a lead frame with a die attach layer.

19. The method of claim 18, wherein the die attach layer is a conductive die attach layer.

20. The method of claim 15, further comprising:
depositing an adhesive layer that separates the insulation layer and the conductive coating layer in the longitudinal direction, wherein the adhesive layer provides adhesion of the conductive coating layer to the insulation layer.
